(19) United States
(12) Patent Application Publication
(10) Pub. No.: US 2026/0096394 A1
(43) Pub. Date: Apr. 2, 2026

(54) CARRIER WAFER STRUCTURE AND STACK STRUCTURE INCLUDING THE SAME

(71) Applicant: SAMSUNG ELECTRONICS CO., LTD., Suwon-si (KR)

(72) Inventor: Taeyeong KIM, Suwon-si (KR)

(73) Assignee: SAMSUNG ELECTRONICS CO., LTD., Suwon-si (KR)

(21) Appl. No.: 19/213,525

(22) Filed: May 20, 2025

(30) Foreign Application Priority Data
Oct. 2, 2024 (KR) 10-2024-0133997

(51) Int. Cl. H01L 21/683; B32B 3/12; B32B 7/12

(52) U.S. Cl. CPC H10P 72/74; B32B 3/12; B32B 7/12; B32B 2307/206; B32B 2307/416

(57) ABSTRACT

A stack structure may include: a device wafer, an adhesive layer on the device wafer, a reflective structure layer on the adhesive layer, the reflective structure layer including: a reflective structure including openings; and a first insulating layer on the reflective structure; a separation layer on the reflective structure layer, and a carrier wafer on the separation layer.

### CROSS-REFERENCE TO RELATED APPLICATION

This application claims priority to and the benefit of Korean Patent Application No. 10-2024-0133997 filed in the Korean Intellectual Property Office on Oct. 2, 2024, the entire contents of which are incorporated herein by reference.

### BACKGROUND

### 1. Field

The present disclosure relates to a carrier wafer structure and a stack structure including the carrier wafer structure.

### 2. Description of Related Art

Recently, a thickness of a wafer has been thinner according to the low power and high performance demands of a semiconductor package. However, as the wafer becomes thinner and wider, a warpage phenomenon increases, and thus a problem may occur in a process of processing the wafer.

To solve this problem, a method of coating an adhesive on one side of a device wafer and then attaching the device wafer to a carrier wafer capable of supporting and transporting the device wafer may be used. Grinding and various semiconductor processes may be performed while the device wafer is coupled to the carrier wafer.

After a semiconductor process is completed, the device wafer needs to be separated from the carrier wafer. To this end, various debonding technologies such as mechanical separation, thermal separation, chemical separation, laser separation, etc. have been proposed.

### SUMMARY

The present disclosure attempts to provide a carrier wafer structure and a stack structure including the carrier wafer structure capable of manufacturing a highly reliable semiconductor device.

The present disclosure also attempts to provide a carrier wafer structure and a stack structure including the carrier wafer structure capable of effectively separating a device wafer during a semiconductor processing process performed while the device wafer is attached to a carrier wafer.

According to an aspect of the disclosure, a stack structure may include: a device wafer; an adhesive layer on the device wafer; a reflective structure layer on the adhesive layer, the reflective structure layer including: a reflective structure including openings; and a first insulating layer on the reflective structure; a separation layer on the reflective structure layer; and a carrier wafer on the separation layer.

According to an aspect of the disclosure, a carrier wafer structure may include: a carrier wafer; a separation layer on the carrier wafer; a reflective structure layer on the separation layer, the reflective structure layer including: a reflective structure including openings; and a first insulating layer on the reflective structure; and an adhesive layer on the reflective structure layer. The separation layer may be configured to absorb energy of a laser transmitted through the carrier wafer to debond a surface of the separation layer, and the reflective structure may be configured to reflect at least a part of the laser transmitted through the carrier wafer to the separation layer.

According to an aspect of the disclosure, a stack structure may include: a device wafer; an adhesive layer on the device wafer; a separation layer on the adhesive layer; a column structure layer on the separation layer, the column structure layer including: column structures having a certain pitch; and an insulating layer on the column structures; and a carrier wafer on the column structure layer.

According to embodiments, it is possible to perform the process of the highly reliable device wafer.

In addition, according to embodiments, the device wafer structure may be easily debonded from the carrier wafer structure.

### BRIEF DESCRIPTION OF THE DRAWINGS

Embodiments will be more clearly understood from the following detailed description taken in conjunction with the accompanying drawings in which:

FIG. 1 is a cross-sectional view of a stack structure according to one or more embodiments;

FIG. 2 is a plan view of a reflective structure according to one or more embodiments;

FIG. 3 is a plan view of a reflective structure according to one or more embodiments;

FIG. 4 is a cross-sectional view of a stack structure according to one or more embodiments;

FIG. 5 is a plan view of a column structure according to one or more embodiments;

FIG. 6 is a cross-sectional view of a stack structure according to one or more embodiments;

FIG. 7 is a cross-sectional view of a carrier wafer structure according to one or more embodiments;

FIG. 8 is a cross-sectional view of a device wafer structure according to one or more embodiments;

FIG. 9 is a diagram for explaining a layer separation process using a laser in a stack structure according to one or more embodiments;

FIG. 10 is a diagram for explaining a layer separation process using a laser in a stack structure according to one or more embodiments; and

FIG. 11 is a diagram for explaining a layer separation process using a laser in a stack structure according to one or more embodiments.

### DETAILED DESCRIPTION

Hereinafter, with reference to the attached drawings, embodiments of the disclosure will be described in detail below so that ordinary skilled in the art may easily implement the disclosure. The present disclosure may be embodied in many different forms and is not limited to the embodiments set forth herein.

In order to clearly explain the present disclosure in the drawings, parts irrelevant to the description are omitted, and the same reference numerals are used for the same or similar elements throughout the specification.

In addition, since the size and thickness of each component shown in the drawings are arbitrarily shown for convenience of description, the present disclosure is not necessarily limited to those shown. In the drawings, the thickness of layers and regions are exaggerated for clarity. In addition, in the drawings, for convenience of explanation, thicknesses of some layers and areas are exaggerated.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity.

In addition, throughout the specification, unless explicitly described to the contrary, the word “comprise”, and variations such as “comprises” or “comprising”, will be understood to imply the inclusion of stated elements but not the exclusion of any other elements.

In addition, throughout the specification, when it is “on a plane” means when a target portion is viewed from above, and when it is “on a cross section” means when a cross section obtained by vertically cutting a target portion is viewed from the side.

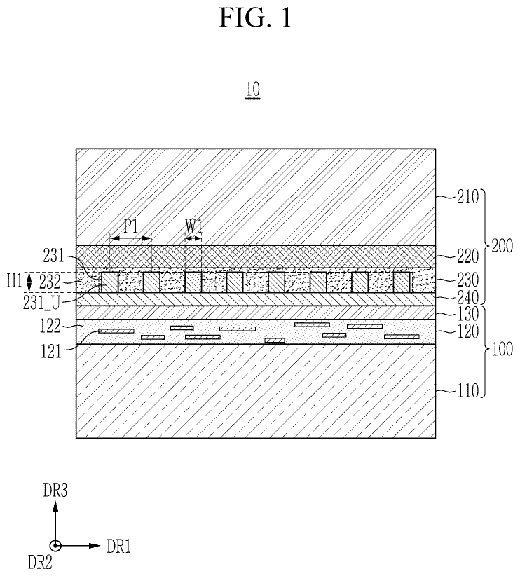

FIG. 1 is a cross-sectional view of a stack structure according to one or more embodiments.

Referring to FIG. 1, a stack structure 10 may include a device wafer structure 100 and a carrier wafer structure 200.

The device wafer structure 100 may include a device wafer 110, a wiring layer 120, and an adhesive layer 130.

The device wafer 110 may refer to a wafer on which a semiconductor device is manufactured. For example, the device wafer 110 may include silicon (Si). In addition, the device wafer 110 may include a semiconductor element such as germanium (Ge), or a compound semiconductor such as silicon carbide (SiC), gallium arsenide (GaAs), Indium Arsenide (InAs), and Indium Phosphide (InP), but is not limited thereto.

The wiring layer 120 may be disposed on the device wafer 110. The wiring layer 120 may be disposed between the device wafer 110 and the adhesive layer 130. The wiring layer 120 may include a wiring pattern 121 including a conductive material and an insulating layer 122 covering the wiring pattern 121.

The wiring pattern 121 may serve to receive an electrical signal from the outside and rewire the electrical signal. One or more wiring patterns 121 may be disposed in the wiring layer 120. The wiring pattern 121 may include a conductive material. For example, the wiring pattern 121 may include copper (Cu), aluminum (Al), silver (Ag), tin (Sn), gold (Au), nickel (Ni), lead (Pb), titanium (Ti), or an alloy thereof, but is not limited thereto.

The insulating layer 122 may cover the wiring pattern 121. The insulating layer 122 may include an insulating material. For example, the insulating layer 122 may include, for example silicon oxide (SiO), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or a combination thereof, but is not limited thereto.

The adhesive layer 130 may be disposed on the wiring layer 120. The adhesive layer 130 may be a configuration for bonding the device wafer structure 100 and the carrier wafer structure 200. The adhesive layer 130 may include an adhesive material. For example, the adhesive layer 130 may include, for example, benzo cyclo butene (BCB), epoxy, polyimide, Teflon (PolyTetraFluoreEthylene (PTFE)), acrylic, a silicone polymer adhesive, and other polymer adhesive materials, but is not limited thereto.

The carrier wafer structure 200 may include a carrier wafer 210, a separation layer 220, a reflective structure layer 230, and an adhesive layer 240.

The carrier wafer 210 may serve to support the carrier wafer structure 200. In addition, the carrier wafer 210 may include silicon (Si). The carrier wafer 210 may include a semiconductor element such as germanium (Ge), or a compound semiconductor such as silicon carbide (SiC), gallium arsenide (GaAs), Indium Arsenide (InAs), and Indium Phosphide (InP), but is not limited thereto.

A laser beam LB, for example, an infrared laser beam LB, supplied to the separation layer 220 may transmit through the carrier wafer 210. The laser beam LB will be described below.

The separation layer 220 may be disposed on one surface of the carrier wafer 210. The separation layer 220 may be disposed between the carrier wafer 210 and the reflective structure layer 230.

The separation layer 220 may serve to separate the device wafer structure 100 from the carrier wafer structure 200. The separation layer 220 may absorb energy from the laser beam LB, obtain thermal energy, and be debonded from a configuration attached to an upper surface or a lower surface of the separation layer 220. For example, the separation layer 220 may receive the laser beam LB to be heated and thermally expanded, and may be debonded due to a difference in a coefficient of thermal expansion with the configuration attached to the upper surface or the lower surface of the separation layer 220. In other words, the separation layer is configured to be separated by the laser.

For example, the separation layer 220 may include at least one of alpha-silicon (a-Si), silicon oxide (SiO), and a metal material. In addition, for example, the separation layer 220 may include at least one of molybdenum (Mo) and germanium (Ge). However, the present disclosure is not limited thereto, and the separation layer 220 may include a material having a high energy absorption rate of the laser beam LB.

The reflective structure layer 230 may be disposed on one surface of the separation layer 220. The reflective structure layer 230 may be disposed between the carrier wafer 210 and the adhesive layer 240. In addition, the reflective structure layer 230 may be disposed between the separation layer 220 and the adhesive layer 240.

The reflective structure layer 230 may include a reflective structure 231 and an insulating layer 232 covering the reflective structure 231.

The reflective structure 231 may be a configuration to reflect the laser beam LB transmitted through the carrier wafer 210. The reflective structure 231 is disposed to be in contact with one surface of the reflective structure layer 230, but is not limited thereto. That is, the reflective structure 231 may be disposed to be in contact with the opposite surface of the reflective structure layer 230, may be disposed at an intermediate position of the reflective structure layer 230, and for example, one surface of the reflective structure 231 may be disposed to be in contact with the adhesive layer 240.

A height H1 of the reflective structure 231 may be equal to or less than a thickness of the reflective structure layer 230. For example, the height H1 of the reflective structure 231 may be about 1 kÅ or more and about 10 kÅ or less, but is not limited thereto.

The reflective structure 231 may include a plurality of unit sidewalls 231_U. The plurality of unit sidewalls 231_U may be regularly disposed within the reflective structure 231. A width W1 of the unit sidewall 231_U constituting the reflective structure 231 may be less than the height H1 of the reflective structure 231. For example, the width W1 of the unit sidewall 231_U of the reflective structure 231 may be about 1/10 of the height H1 of the reflective structure 231, but is not limited thereto. For example, when the height H1 of the reflective structure 231 is about 1 kÅ or more and about 10 kÅ or less, the width W1 of the unit sidewall 231_U of the reflective structure 231 may be about 100 Å or more and about 1 kÅ or less.

A pitch between the unit sidewalls 231_U facing each other in the reflective structure 231 may be a first pitch P1. A distance between centers of the unit sidewalls 231_U facing each other in the reflective structure 231 may be the first pitch P1. In addition, a distance between centers of openings 231_O adjacent to each other may be the first pitch P1.

The unit sidewall 231_U of the reflective structure 231 may include a metal material or a nitride compound. The unit sidewall 231_U of the reflective structure 231 may include, for example, aluminum (Al), copper (Cu), or a compound thereof. In addition, the unit sidewall 231_U of the reflective structure 231 may include, for example, metal nitride, non-metal nitride, semiconductor nitride, or a compound thereof.

The height H1 of the reflective structure 231 may refer to a height of the unit sidewall 231_U.

The insulating layer 232 may cover the reflective structure 231, and may include an insulating material. For example, the insulating layer 232 may include silicon oxide (SiO), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or a combination thereof, but is not limited thereto.

The adhesive layer 240, which is a configuration for bonding the device wafer structure 100 and the carrier wafer structure 200, may include an adhesive material. The adhesive layer 240 of the carrier wafer structure 200 may be in contact with the adhesive layer 130 of the device wafer structure 100 and may be bonded to each other.

For example, the adhesive layer 240 may include, for example, Benzo Cyclo Butene (BCB), epoxy, polyimide, Teflon (PolyTetraFluoreEthylene (PTFE)), acrylic, a silicone polymer adhesive, and other polymer adhesive materials, but is not limited thereto.

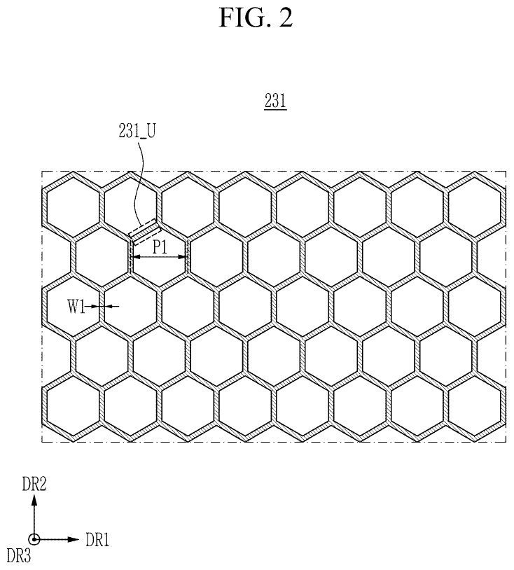

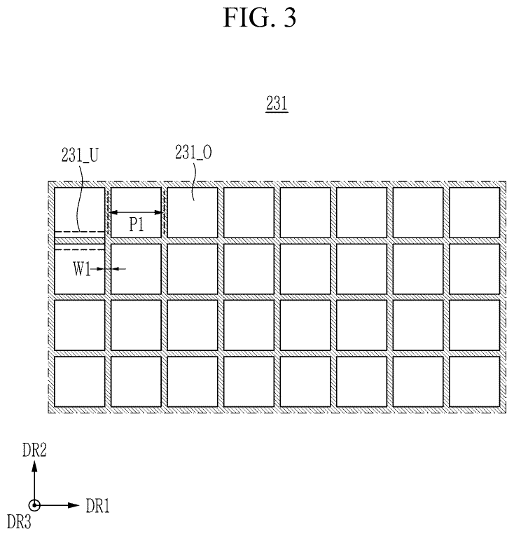

FIG. 2 is a plan view of a reflective structure according to one or more embodiments. FIG. 3 is a plan view of a reflective structure according to another embodiment.

Referring to FIGS. 2 and 3, the reflective structure 231 according to one or more embodiments may have a honeycomb structure as shown in FIG. 2 or a grid structure as shown in FIG. 3, but is not limited thereto.

The reflective structure 231 may include the plurality of unit sidewalls 231_U and the one or more openings 231_O defined by the plurality of unit sidewalls 231_U. The insulating layer 232 may cover the reflective structure 231, and may be disposed in the opening 231_O.

The plurality of unit sidewalls 231_U may be regularly disposed within the reflective structure layer 230. For example, the plurality of unit sidewalls 231_U may be regularly disposed such that side surfaces thereof contact each other, but are not limited thereto. For example, the plurality of unit sidewalls 231_U may be regularly disposed to form a hexagonal structure as shown in FIG. 2, and may also be arranged to form a rectangular structure as shown in FIG. 3. When the plurality of unit sidewalls 231_U are regularly disposed to form the hexagonal shape, the opening 231_O may be defined by being surrounded by the six unit sidewalls 231_U, in a plan view, the opening 231_O may have the hexagonal shape, and, for example, the opening 231_O as viewed in a third direction DR3 may have the hexagonal shape. In addition, when the plurality of unit sidewalls 231_U are regularly disposed to form the rectangular structure, the opening 231_O may be defined by being surrounded by the four unit sidewalls 231_U, in a plan view, the opening 231_O may have the rectangular shape, and, for example, the opening 231_O as viewed in the third direction DR3 may have the rectangular shape. For example, the opening 231_O viewed from the third direction DR3 may have a square or regular hexagonal shape, but is not limited thereto.

A pitch between the unit sidewalls 231_U facing each other in the reflective structure 231 may be the first pitch P1. A distance between centers of the unit sidewalls 231_U facing each other in the reflective structure 231 may be the first pitch P1. In addition, a distance between centers of the openings 231_O adjacent to each other may be the first pitch P1. For example, the first pitch P1 may be about ⅕ or more and about ½ or less of a wavelength of the laser beam LB. For example, when the wavelength of the laser beam LB is 1030 nm, the first pitch P1 may be 206 nm or more and 515 nm or less.

The opening 231_O may have a shape extending in the third direction DR3. The opening 231_O may have a shape of a hexagonal column or a rectangular column.

The reflective structure 231 includes the one or more openings 231_O, but may reflect the laser beam LB. For example, the wavelength of the incident laser beam LB may be greater than the size of the opening 231_O, and because a diffraction phenomenon of the laser beam LB does not occur, the laser beam LB may be reflected from the reflective structure 231.

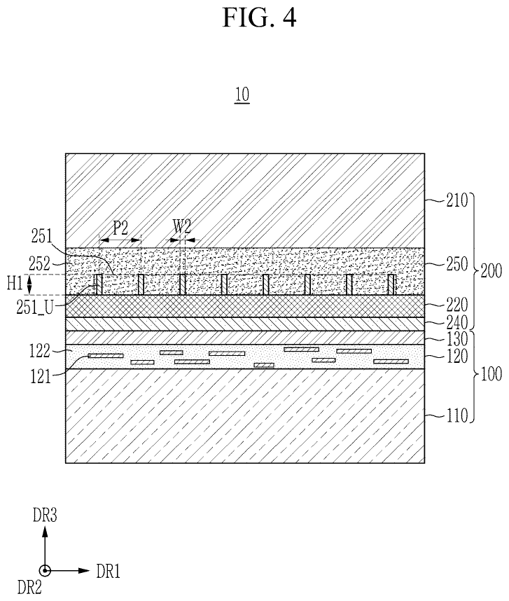

FIG. 4 is a cross-sectional view of a stack structure according to another embodiment.

Referring to FIG. 4, the stack structure 10 may include the device wafer structure 100 and the carrier wafer structure 200.

The device wafer structure 100 may include the device wafer 110, the wiring layer 120, and the adhesive layer 130.

The carrier wafer structure 200 may include the carrier wafer 210, a column structure layer 250, the separation layer 220, and the adhesive layer 240.

The column structure layer 250 may be disposed on one surface of the carrier wafer 210. The column structure layer 250 may be disposed between the adhesive layer 240 and the carrier wafer 210. The column structure layer 250 may be disposed between the carrier wafer 210 and the separation layer 220.

The column structure layer 250 may include a column structure group 251 and an insulating layer 252.

The column structure group 251 may be a configuration to allow the laser beam LB transmitted through the carrier wafer 210 to transmit therethrough. The column structure group 251 is disposed to be in contact with one surface of the column structure layer 250, but is not limited thereto. That is, the column structure group 251 may be disposed to be in contact with the opposite surface of the column structure layer 250, and may be disposed at a middle position of the column structure layer 250. For example, one surface of the column structure group 251 may be disposed to be in contact with the separation layer 220.

A height H2 of the column structure group 251 may be equal to or less than a thickness of the column structure layer 250. For example, the height H2 of the column structure group 251 may be about 1 kÅ or more and about 10 kÅ or less, but is not limited thereto.

A column unit structure 251_U included in the column structure group 251 may be referred to as a column structure. A width W2 of the column unit structure 251_U (column structures) of the column structure group 251 may be less than the height H2 of the column structure group 251. For example, the width W2 of the column unit structure 251_U may be about 1/10 of the height H2 of the column structure group 251, but is not limited thereto. For example, when the height H2 of the column structure group 251 is about 1 kÅ or more and about 10 kÅ or less, the width W2 of the column unit structure 251_U of the column structure group 251 may be about 100 Å or more and about 1 kÅ or less.

A pitch between the column unit structures 251_U adjacent to each other may be a second pitch P2. A distance between centers of the column unit structures 251_U adjacent to each other may be the second pitch P2.

The column unit structure 251_U of the column structure group 251 may include a metal material or a nitride compound. For example, the column unit structure 251_U may include aluminum (Al), copper (Cu), or a compound thereof. In addition, the column unit structure 251_U may include, for example, a metal nitride, a non-metal nitride, a semiconductor nitride, or a compound thereof.

The height H2 of the column structure group 251 may refer to the height of the column unit structure 251_U.

The column structure layer 250 may be referred to as the meta structure layer. The column structure group 251 may be referred to as the meta structure group. The column unit structure 251_U may be referred to as the meta unit structure or meta structure. A meta structure may refer to an artificial structure designed to manipulate or enhance the physical, electromagnetic, or mechanical properties of waves such as light, sound, heat, and elastic waves, or external physical forces. In the embodiment, an example of the meta structure layer is provided as a column structure layer in which metal structures having a predetermined width and pitch are arranged. However, the meta structure layer is not limited thereto. For example, the column structure layer may be replaced with a dielectric meta-structure, a photonic crystal based on a periodic lattice, or a plasmonic meta-structure.

The insulating layer 252 may cover the column structure group 251, and may include an insulating material. For example, the insulating layer 252 may include, for example, silicon oxide (SiO), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or a combination thereof, but is not limited thereto.

The separation layer 220 may be disposed on one surface of the column structure layer 250. The separation layer 220 may be disposed between the column structure layer 250 and the adhesive layer 240. The adhesive layer 240 may be disposed on one surface of the separation layer 220.

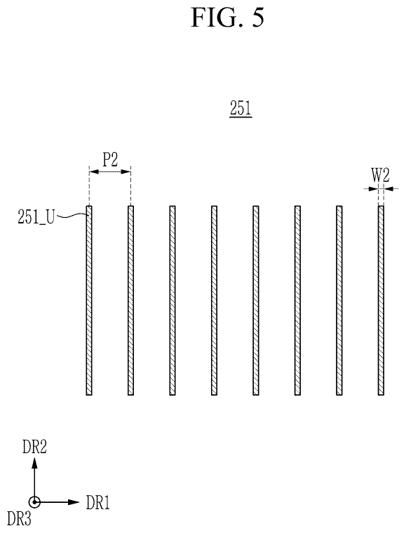

FIG. 5 is a plan view of a column structure according to one or more embodiments.

Referring to FIG. 5, the column structure group 251 may include the one or more column unit structures 251_U. The one or more column unit structures 251_U may be regularly disposed in the column structure layer 250. For example, the one or more column unit structures 251_U may be disposed to be spaced apart from each other at a certain distance, but are not limited thereto.

The column unit structure 251_U may have a bar shape, but is not limited thereto. For example, the column unit structure 251_U may have a long rectangular column shape extending in one direction. For example, the column unit structure 251_U may have a shape extending in a second direction DR2, but is not limited thereto. That is, the column unit structure 251_U may have a shape extending in the first direction DR1 or an oblique direction between the first direction DR1 and the second direction DR2.

A pitch between the column unit structures 251_U adjacent to each other may be the second pitch P2. A distance between centers of the column unit structures 251_U adjacent to each other may be the second pitch P2. For example, the second pitch P2 may be about ¼ or more and about ½ or less of a wavelength of the laser beam LB. For example, when the wavelength of the laser beam LB is 1030 nm, the second pitch P2 may be 257.5 nm or more and 515 nm or less.

The column structure group 251 may allow the laser beam LB to transmit therethrough via a distance between the column unit structures 251_U. For example, the wavelength of the laser beam LB incident in the third direction DR3 may be greater than the distance between the column unit structures 251_U, a component of the laser beam LB vibrating in the second direction DR2 may pass through the column structure group 251, and because the other laser beam LB includes a part of the component of the laser beam LB vibrating in the first direction DR1, a path between the column unit structures 251_U is formed, and thus, a time that the laser beam LB stays in the column structure group 251 may be increased. In addition, the laser beam LB may be supplied to the separation layer 220 through leakage of the component of the laser beam LB vibrating in the first direction DR1.

Accordingly, a time that the laser beam LB stays at an interface between the separation layer 220 and the column structure group 251 may be increased, and the separation layer 220 may effectively absorb energy of the laser beam LB.

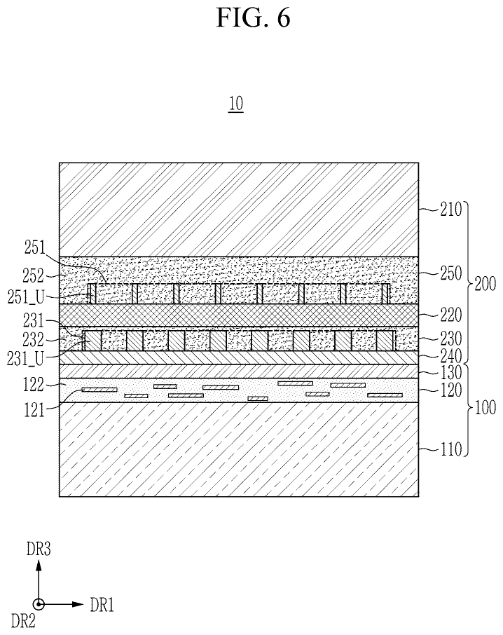

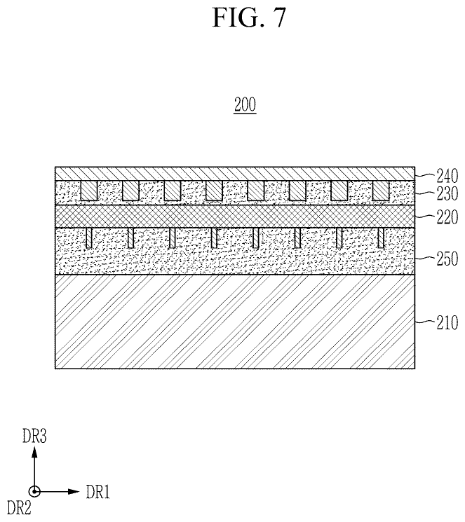

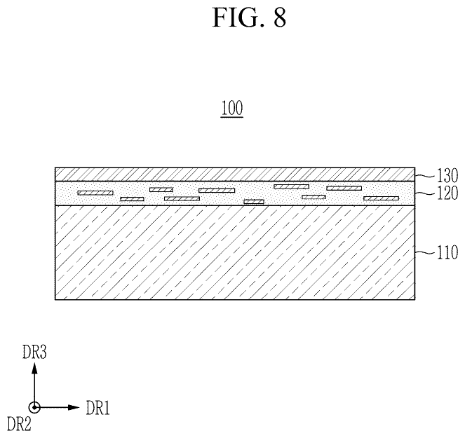

FIG. 6 is a cross-sectional view of a stack structure according to another embodiment. FIG. 7 is a cross-sectional view of a carrier wafer structure according to one or more embodiments. FIG. 8 is a cross-sectional view of a device wafer structure according to one or more embodiments.

Referring to FIGS. 6 to 8, the stack structure 10 according to one or more embodiments may include the device wafer structure 100 and the carrier wafer structure 200.

The device wafer structure 100 may include the device wafer 110, the wiring layer 120, and the adhesive layer 130. The carrier wafer structure 200 may include the carrier wafer 210, the column structure layer 250, the separation layer 220, the reflective structure layer 230, and the adhesive layer 240. That is, the stack structure 10 may simultaneously include the column structure layer 250 and the reflective structure layer 230.

For example, the column structure layer 250 may allow the laser beam LB transmitted through the carrier wafer 210 and supplied in the third direction DR3 to transmit therethrough, and the reflective structure layer 230 may reflect the incident laser beam LB. Accordingly, the laser beam LB may be effectively supplied to the separation layer 220, the separation layer 220 may absorb energy from the laser beam LB, and the device wafer structure 100 and the carrier wafer structure 200 may be effectively separated.

In the stack structure 10, the adhesive layer 130 of the device wafer structure 100 and the adhesive layer 240 of the carrier wafer structure 200 may contact each other to be adhered to each other.

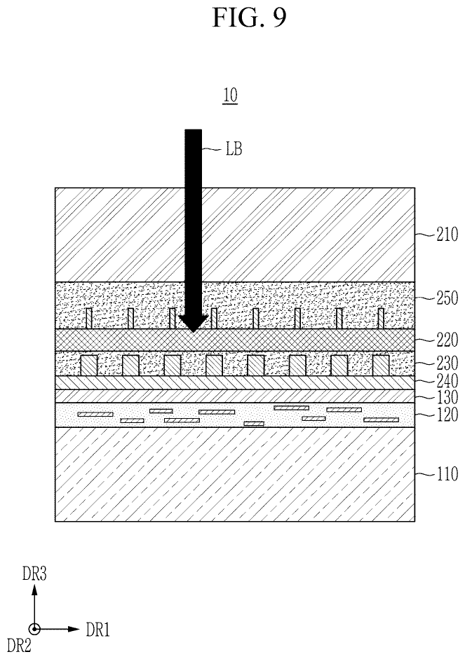

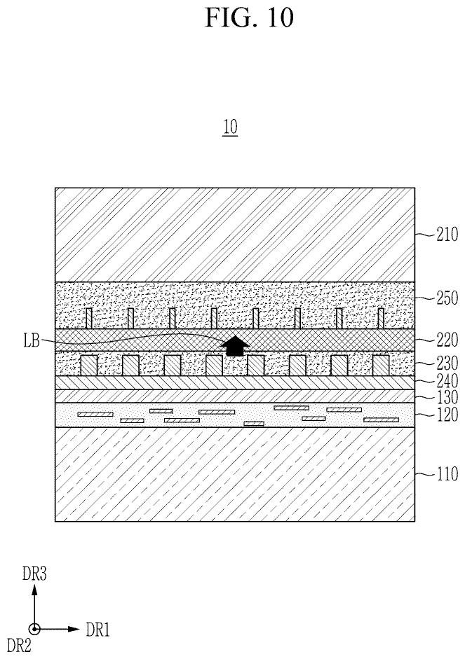

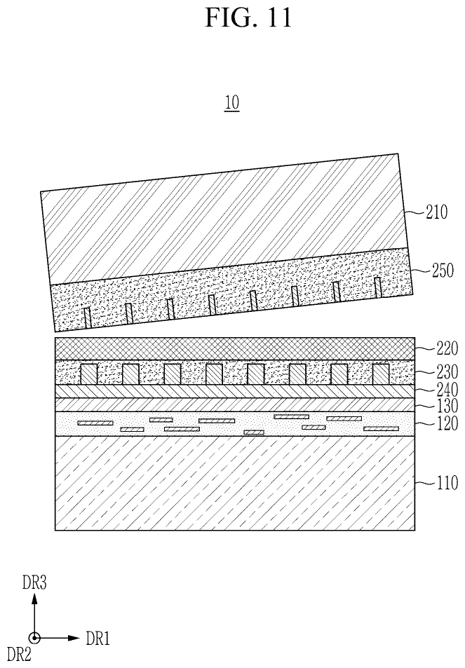

FIGS. 9 to 11 are diagrams for explaining a layer separation process using a laser in a stack structure according to one or more embodiments.

Referring to FIGS. 9 to 11, the laser beam LB may be supplied to the separation layer 220 to separate the device wafer structure 100 from the carrier wafer structure 200. The laser beam LB may transmit through the carrier wafer 210, and the laser beam LB transmitted through the carrier wafer 210 may be supplied to the separation layer 220. For example, the laser beam LB may be irradiated to the carrier wafer 210 in the third direction DR3, but is not limited thereto.

A wavelength of the laser beam LB may be 1000 nm or more and 10000 nm or less. For example, the wavelength of the laser beam LB may be 1000 nm or more and 1100 nm or less, or 9000 nm or more and 10000 nm or less. For example, the wavelength of the laser beam LB may be 1030 nm or 9300 nm.

The laser beam LB supplied in the third direction DR3 may transmit through the carrier wafer 210 and be supplied to the column structure layer 250 before being supplied to the separation layer 220. The column structure layer 250 may transmit through the laser beam LB and reduce reflection of the laser beam LB at an interface between the column structure layer 250 and the separation layer 220.

The separation layer 220 may absorb energy from the supplied laser beam LB. The separation layer 220 may absorb the energy from the laser beam LB, obtain thermal energy, and be debonded from a configuration attached to the upper surface or a lower surface of the separation layer 220.

The laser beam LB transmitted through the separation layer 220 may be supplied to the reflective structure layer 230. The reflective structure layer 230 may reflect the supplied laser beam LB. The reflective structure layer 230 may supply the laser beam LB transmitted through the separation layer 220 to the separation layer 220 again, thereby preventing the laser beam LB from being supplied to a layer other than the separation layer 220 and the energy of the laser beam LB from being absorbed, and effectively helping the separation layer 220 absorb the energy of the laser beam LB.

The separation layer 220 may receive the laser beam LB to be heated and thermally expanded, and may be debonded due to a difference in a coefficient of thermal expansion with the configuration attached to the upper surface or the lower surface of the separation layer 220.

Although the embodiments of the disclosure have been described in detail above, the scope of the disclosure is not limited thereto, and various modifications and improvements made by those of ordinary skill in the field also belong to the scope of the disclosure.

What is claimed is:

1. A stack structure comprising:
a device wafer;
an adhesive layer on the device wafer;
a reflective structure layer on the adhesive layer, the reflective structure layer comprising:
a reflective structure comprising openings; and
a first insulating layer on the reflective structure;
a separation layer on the reflective structure layer; and
a carrier wafer on the separation layer.

2. The stack structure of claim 1, wherein:
the separation layer is configured to be separated by a laser having a wavelength of 1000 nm or more and 10000 nm or less.

3. The stack structure of claim 1, wherein:
the reflective structure has a honeycomb structure, and the openings have hexagonal shapes.

4. The stack structure of claim 1, wherein:
the reflective structure has a grid structure, and the openings have rectangular shapes.

5. The stack structure of claim 1,
wherein the separation layer is configured to be separated by a laser, and
wherein the reflective structure comprises side walls that are regularly arranged, and a pitch of the side walls is ⅕ or more and ½ or less of a wavelength of the laser.

6. The stack structure of claim 5, wherein:
widths of the side walls are 1/10 of a height of the reflective structure.

7. The stack structure of claim 1, wherein:
a height of the reflective structure is 1 kÅ or more and 10 kÅ or less.

8. The stack structure of claim 1, further comprising:
a column structure layer between the carrier wafer and the separation layer, comprising column structures having a certain pitch, and a second insulating layer on the column structures.

9. The stack structure of claim 8, wherein:
the column structures are bar shaped and extend in one direction.

10. The stack structure of claim 8,
wherein the separation layer is configured to be separated by a laser, and
wherein the column structures have a pitch of ¼ or more and ½ or less of a wavelength of a laser.

11. The stack structure of claim 8, wherein:
heights of the column structures are 1 kÅ or more and 10 kÅ or less.

12. The stack structure of claim 8, wherein:
widths of the column structures are 1/10 of heights of the column structures.

13. The stack structure of claim 1, further comprising:
a wiring layer between the device wafer and the adhesive layer.

14. A carrier wafer structure comprising:
a carrier wafer;
a separation layer on the carrier wafer;
a reflective structure layer on the separation layer, the reflective structure layer comprising:
a reflective structure comprising openings; and
a first insulating layer on the reflective structure; and
an adhesive layer on the reflective structure layer,
wherein the separation layer is configured to absorb energy of a laser transmitted through the carrier wafer to debond a surface of the separation layer, and the reflective structure is configured to reflect at least a part of the laser transmitted through the carrier wafer to the separation layer.

15. The carrier wafer structure of claim 14, wherein:
the reflective structure has a honeycomb structure, and the openings have hexagonal shapes.

16. The carrier wafer structure of claim 14, wherein:
the reflective structure has a grid structure, and the openings have rectangular shapes.

17. The carrier wafer structure of claim 14, further comprising:
a column structure layer between the carrier wafer and the separation layer and comprising column structures having a certain pitch, and a second insulating layer on the column structures.

18. The carrier wafer structure of claim 17, wherein:
the column structures are bar shaped and extend in one direction.

19. A stack structure comprising:
a device wafer;
an adhesive layer on the device wafer;
a separation layer on the adhesive layer;
a column structure layer on the separation layer, the column structure layer comprising:
column structures having a certain pitch; and
an insulating layer on the column structures; and
a carrier wafer on the column structure layer.

20. The stack structure of claim 19, wherein:
the column structures are bar shaped and extend in one direction.
